(19) United States
(12) Patent Application Publication
(10) Pub. No.: US 2026/0004855 A1
(43) Pub. Date: Jan. 1, 2026

(54) MEMORY DEVICE PERFORMING INFORMATION DATA READ OPERATION AND INFORMATION DATA READ METHOD THEREOF

(71) Applicant: SAMSUNG ELECTRONICS CO., LTD., Suwon-si (KR)

(72) Inventors: Wonkyun Jeong, Suwon-si (KR); Hyunkook Park, Suwon-si (KR); Sungmook Lim, Suwon-si (KR); Ji-Sang Lee, Suwon-si (KR)

(21) Appl. No.: 19/012,628

(22) Filed: Jan. 7, 2025

(30) Foreign Application Priority Data
Jul. 1, 2024 (KR) 10-2024-0086216

(51) Int. Cl. G11C 16/26; G11C 16/04; G11C 16/24; G11C 16/30

(52) U.S. Cl. CPC G11C 16/26; G11C 16/0483; G11C 16/24; G11C 16/30

(57) ABSTRACT

A memory device is disclosed which includes a first bit line connected to a first cell string; a second bit line connected to a second cell string and adjacent to the first bit line; and a bit line precharge controller configured to control voltage levels of the first and second bit lines during an information data read operation to read data stored in the first cell string. The bit line precharge controller precharges the first bit line, provides a boost voltage to the second bit line, and then senses the data stored in the first cell string. The precharge voltage level of the first bit line is increased by the boost voltage provided to the second bit line.

### CROSS-REFERENCE TO RELATED APPLICATION(S)

This application claims priority under 35 U.S.C. § 119 to Korean Patent Application No. 10-2024-0086216 filed on Jul. 1, 2024, in the Korean Intellectual Property Office, the disclosure of which is incorporated by reference herein in its entirety.

### BACKGROUND

Example implementations of the present disclosure described herein relate to a semiconductor memory device, and more specifically, to a memory device that performs an information data read operation and a method for reading information data thereof.

A semiconductor memory may be mainly classified as a volatile memory or a non-volatile memory. Read and write speeds of the volatile memory (e.g., a dynamic random access memory (DRAM) or a static random access memory (SRAM)) are fast, but the data stored in the volatile memory disappear when a power is turned off. In contrast, the non-volatile memory may retain data even when the power is turned off.

A representative example of the non-volatile memory is a flash memory. The flash memory may store multi-bit data of two or more bits in one memory cell. The flash memory (that stores the multi-bit data) may have one erase state and a plurality of program states depending on threshold voltage distributions.

The flash memory may perform an operation to read information data stored in memory cells when powered up. This operation is called an information data read operation IDR. The external voltage provided to the flash memory may gradually decrease in accordance with the trend towards lower power consumption. Due to a decrease in external voltage, the internal voltage of the flash memory may also decrease. If the internal voltage of the flash memory decreases, sufficient sensing margin for reading information data may not be secured during power-up.

### SUMMARY

Example implementations of the present disclosure provide a memory device that may secure a sufficient sensing margin for reading information data during power-up and a method for reading information data thereof.

According to some implementations, a memory device comprises, a first bit line connected to a first cell string; and a second bit line connected to a second cell string and adjacent to the first bit line. Wherein, during an information data read operation, the first bit line is precharged, a boost voltage is applied to the second bit line, the precharge voltage level of the first bit line is increased due to a couple cap parasitically existing between the first and second bit lines, and then data stored in the first cell string is sensed.

According to some implementations, a memory device comprises, a first bit line connected to a first cell string; a second bit line connected to a second cell string and adjacent to the first bit line; and a bit line precharge controller configured to control voltage levels of the first and second bit lines during an information data read operation to read data stored in the first cell string. Wherein the bit line precharge controller precharges the first bit line, provides a boost voltage to the second bit line, and then senses the data stored in the first cell string. And wherein the precharge voltage level of the first bit line is increased by the boost voltage provided to the second bit line.

According to some implementations, a method for reading information data of a memory device which includes a first bit line connected to a first cell string, and a second bit line connected to a second cell string and adjacent to the first bit line, the method for reading information data of the memory device comprises, during an information data read operation, precharging the first bit line; applying a boost voltage to the second bit line; developing the first bit line; performing a charge sharing operation between the first bit line and a sensing node; and sensing data stored in the first cell string. Wherein the precharge voltage level of the first bit line is increased due to a couple cap that exists parasitically between the first bit line and the second bit line when the boost voltage is applied to the second bit line.

### BRIEF DESCRIPTION OF THE FIGURES

The above and other objects and features of the present disclosure will become apparent by describing in detail implementations thereof with reference to the accompanying drawings.

FIG. 1 is a block diagram illustrating some implementations of a storage device according to the present disclosure.

FIG. 2 is a block diagram illustrating as some implementations of the memory device illustrated in FIG. 1.

FIG. 3 is a circuit diagram illustrating some implementations of a memory block BLK1 of the memory cell array illustrated in FIG. 2.

FIG. 4 is a circuit diagram illustrating cell strings selected by the first string selection line SSL1 from among the cell strings of the memory block BLK1 illustrated in FIG. 3.

FIG. 5 is a diagram illustrating some implementations of threshold voltage distributions of memory cells illustrated in FIG. 4.

FIG. 6 is a circuit diagram illustrating the first page buffer PB1 shown in FIG. 5.

FIGS. 7 to 9 illustrate some implementations of an information data read operation of the first page buffer illustrated in FIG. 6.

FIG. 10 is a circuit diagram illustrating some implementations of memory device according to the present disclosure.

FIGS. 11 to 13 illustrate some implementations of an information data read operation of a memory device according to the present disclosure.

FIGS. 14 to 17 illustrate some implementations of a method for performing an information data read operation using a GSL coding method.

FIGS. 18 to 20 illustrate some implementations of a method for performing an information data read operation using a cell patterning method.

FIG. 21 is a diagram illustrating some implementations of a memory device having a multi-stack structure.

FIG. 22 is a block diagram illustrating an example in which a storage device according to some implementations of the present disclosure is implemented with a solid state drive (SSD).

### DETAILED DESCRIPTION

Below, example implementations of the present disclosure will be described in detail and clearly to such an extent that an ordinary one in the art easily implements them.

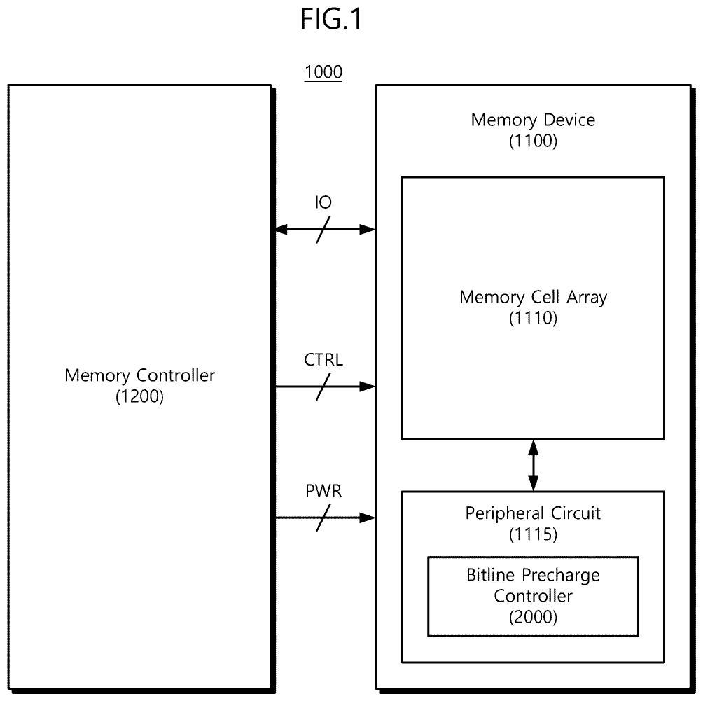

FIG. 1 is a block diagram illustrating some implementations of a storage device according to the present disclosure.

Referring to FIG. 1, the storage device 1000 may include a memory device 1100 and a memory controller 1200. The storage device 1000 may be a flash storage device based on a flash memory. For example, the storage device 1000 may be implemented as a solid-state drive (SSD), a universal flash storage (UFS), a memory card, or the like.

The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may have a vertical 3D structure. The memory cell array 1110 may include a plurality of memory cells. Multi-bit data may be stored in each memory cell.

The memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure.

The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200.

The peripheral circuit 1115 may include a bit line precharge controller 2000. The bit line precharge controller 2000 may control an information data read operation when the memory device 1100 is booted. The bit line precharge controller 2000 may increase the sensing margin of information data by using capacitance coupling that exists parasitically between neighboring bit lines. Hereinafter, the parasitic capacitance that causes capacitance coupling is referred to as a couple cap.

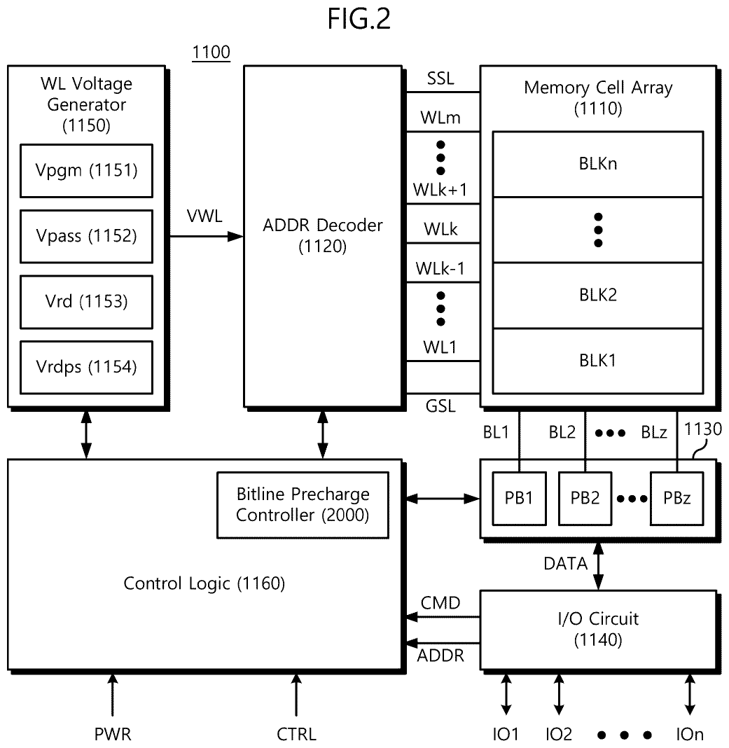

FIG. 2 is a block diagram illustrating some implementations of the memory device illustrated in FIG. 1.

FIG. 2 is a block diagram illustrating some implementations of the memory device illustrated in FIG. 1. Referring to FIG. 2, the memory device 1100 may include the memory cell array 1110 and the peripheral circuit 1115 (see FIG. 1). The peripheral circuit 1115 may include an address decoder 1120, a page buffer circuit 1130, a data input/output circuit 1140, a word line voltage generator 1150, and a control logic 1160.

The memory cell array 1110 may include a plurality of memory blocks BLK1 to BLKn. Each memory block may include a plurality of pages. Each page may include a plurality of memory cells. Each memory cell may store multi-bit data (e.g., two or more bits). Each memory block may correspond to an erase unit, and each page may correspond to a read and/or write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selected word line sWL and the remaining word lines (WL1 to WLk−1, WLk+1 to WLm) are unselected word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selected word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller 1200 (refer to FIG. 1) through the input/output lines IO1 to IOn. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selected word line sWL or unselected word lines uWL through the address decoder 1120.

The word line voltage generator 1150 may include a program voltage generator 1151 and a pass voltage generator 1152. The program voltage generator 1151 may generate a program voltage Vpgm provided to the selected word line sWL during a program operation. The pass voltage generator 1152 may generate a pass voltage Vpass provided to the selected word line sWL and the unselected word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselected word lines uWL. The read pass voltage Vrdps may be a voltage sufficient to turn on memory cells connected to the unselected word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

The control logic 1160 may include a bit line precharge controller 2000. The bit line precharge controller 2000 may perform an information data read operation using a couple cap that parasitically exists between neighboring bit lines when the memory device 1100 is booted. The bit line precharge controller 2000 may increase the sensing margin of information data of the selected bit line by using a couple cap between the selected bit line and the unselected bit line during an information data read operation.

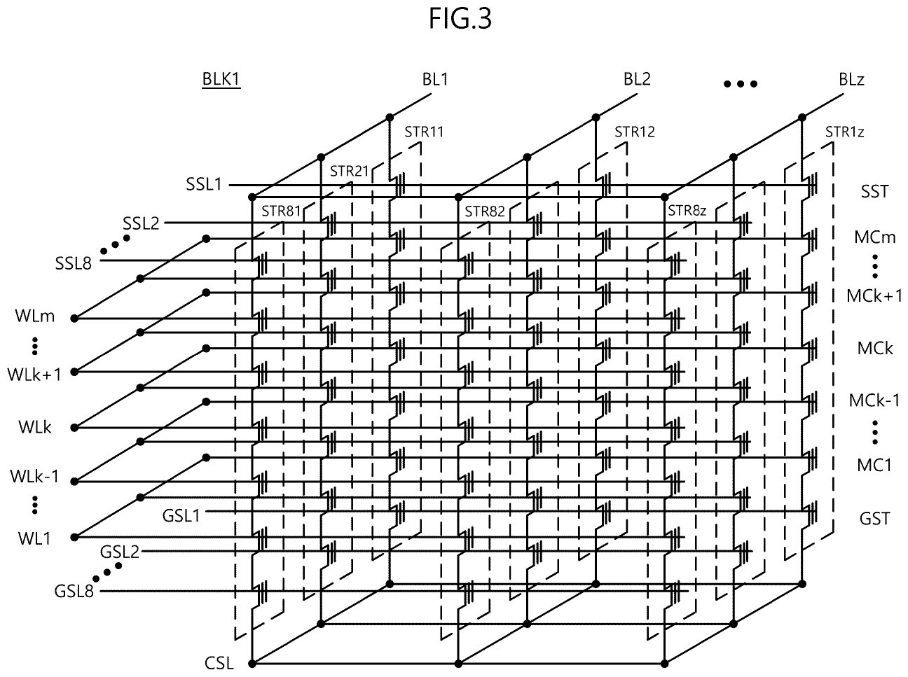

FIG. 3 is a circuit diagram illustrating some implementations of a memory block BLK1 of the memory cell array illustrated in FIG. 2.

FIG. 3 is a circuit diagram illustrating some implementations of a memory block BLK1 of the memory cell array illustrated in FIG. 2. Referring to FIG. 3, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLZ, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLZ.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

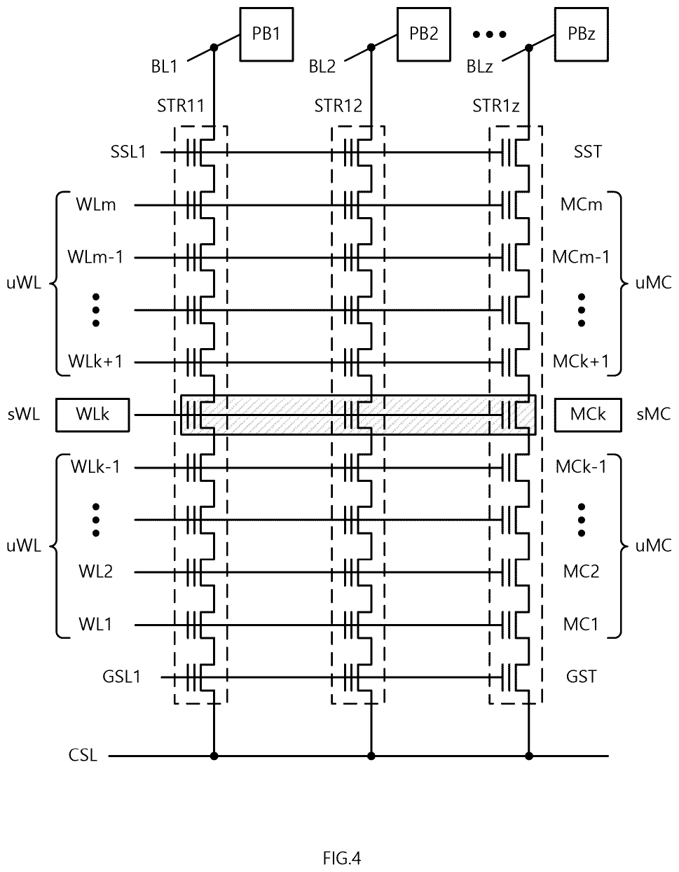

FIG. 4 is a circuit diagram illustrating cell strings selected by the first string selection line SSL1 from among the cell strings of the memory block BLK1 illustrated in FIG. 3.

The 1-1th to 1z-th cell strings STR11 to STR1z may be selected by the first string selection line SSL1. The 1-1th to 1z-th cell strings STR11 to STR1z may be connected to the first to z-th bit lines BL1 to BLz, respectively. The first to z-th page buffers PB1 to PBz may be connected to the first to z-th bit lines BL1 to BLz, respectively.

The 1-1th cell string STR11 may be connected to the first bit line BL1 and the common source line CSL. The 1-1th cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The 1-2th cell string STR12 may be connected to the second bit line BL2 and the common source line CSL. The 1z cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. The k-th word line WLk may be a selected word line sWL. The (k−1)-th word line WLk−1 and the (k+1)-th word line WLk+1 may be adjacent word lines adjacent to the selected word line. If the k-th word line WLk is the selected word line sWL, the remaining word lines WL1 to WLk−1 and WLk+1 to WLm may be unselected word lines uWL.

The first memory cells MC1 and the m-th memory cells MCm may be edge memory cells. The second memory cells MC2 and the (m−1)-th memory cells MCm−1 may be edge adjacent memory cells. The k-th memory cells MCk may be selected memory cells sMC. The (k−1)-th memory cells MCk−1 and the (k+1)-th memory cells MCk+1 may be memory cells adjacent to the selected memory cells (adjacent MC). If the k-th memory cells MCK are selected memory cells sMC, the remaining memory cells MC1 to MCk−1 and MCk+1 to MCm may be unselected memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

The first word line WL1 is a first edge word line (Edge1 WL), and the second word line WL2 is a first edge adjacent word line (Edge1 adjacent WL). The m-th word line WLm is the second edge word line (Edge2 WL), and the (m−1)-th word line WLm−1 is the second edge adjacent word line (Edge2 adjacent WL). And word lines between the first and second edge adjacent word lines are middle word lines. For example, the k-th word line WLk (k=3 to m−2) between the second word line WL2 and the (m−1)-th word line WLm−1 is a middle word line.

In the read operation, if the second word line WL2 is the selected word line sWL, the remaining word lines may be unselected word lines uWL. The second word line WL2 may be a first edge adjacent word line (Edge1 adjacent WL). The second memory cells MC2 may be selected memory cells sMC. The remaining memory cells may be unselected memory cells uMC.

If the (m−1)-th word line WLm−1 is the selected word line sWL, the remaining word lines may be unselected word lines uWL. The (m−1)-th word line WLm−1 may be a second edge adjacent word line. The (m−1)-th memory cells MCm−1 may be selected memory cells sMC. The remaining memory cells may be unselected memory cells uMC.

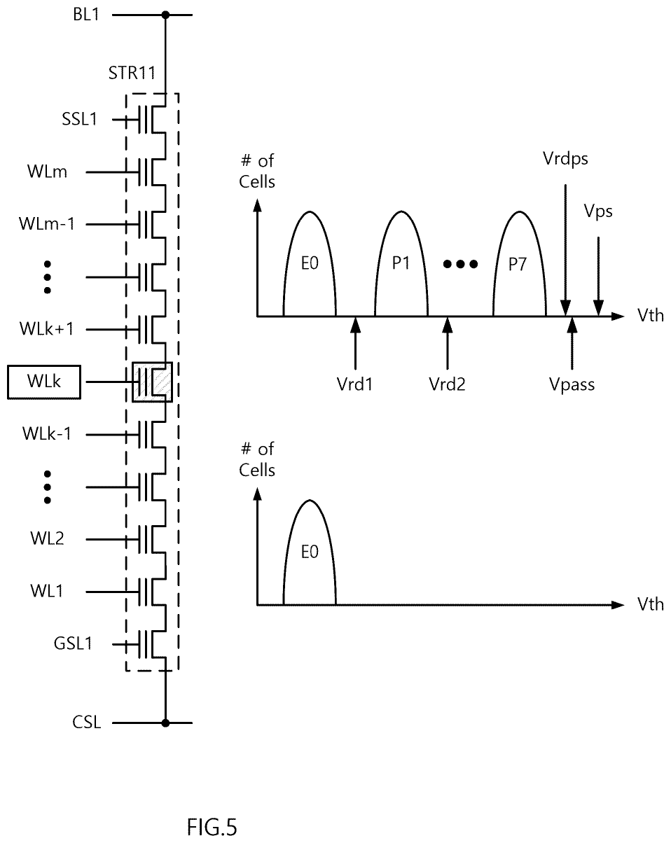

FIG. 5 is a diagram illustrating some implementations of threshold voltage distributions of memory cells illustrated in FIG. 4.

The horizontal axis represents the threshold voltage Vth, and the vertical axis represents the number of memory cells. 3-bit data may be stored in one memory cell. A 3-bit memory cell may have one of eight states (E0, P1 to P7) according to the threshold voltage distribution. E0 (or E) represents an erase state, and P1 to P7 (or P) represent program states.

During a read operation, the selection read voltages Vrd1 to Vrd7 may be provided to the selected word line sWL, and the pass voltage Vps and/or the read pass voltage Vrdps may be provided to the unselected word lines uWL. The pass voltage Vps and/or the read pass voltage Vrdps may be a voltage sufficient to turn on the memory cells. For example, the pass voltage Vps may be provided to the adjacent word lines WLk+1, and the read pass voltage Vrdps may be provided to the unselected word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

When the first selection read voltage Vrd1 is applied, the memory cell in the erase state E0 may be an on cell and the memory cell in the first to seventh program states P1 to P7 may be an off cell. When the second selection read voltage Vrd2 is applied, the memory cell in the erase state E0 and the first program state P1 may an on cell, and the memory cell in the second to seventh program states P2 to P7 may an off cell. In this way, when the seventh selection read voltage Vrd7 is applied, the memory cell in the erase state E0 and the first to sixth program states P1 to P6 may be an on cell and the memory cell in the seventh program state P7 may be an off cell.

During a read operation, the k-th word line WLk may be selected. A power supply voltage may be applied to the string selection line SSL1 and the ground selection line GSL1, and the string selection transistor SST and the ground selection transistor GST may be turned on. Also, the selection read voltage Vrd may be provided to the selected word line sWL, and the read pass voltage Vrdps and/or the pass voltage Vps may be provided to the unselected word lines uWL.

When the read operation of the k-th word line WLk is repeatedly performed, the high voltage read pass voltage Vrdps may be repeatedly provided to the remaining word lines. At this time, a read disturbance may occur in the remaining word lines, and thus the threshold voltage may be distorted. Memory cells connected to the k-th word line WLk may be off cells when a selection read voltage is provided. That is, when the threshold voltage of the k-th memory cell is higher than the selection read voltage, the k-th memory cell may be an off cell. When the k-th memory cell is an off cell, a channel may be separated at the k-th memory cell. That is, a lower channel of the k-th memory cell may receive a ground voltage from the common source line CSL, and an upper channel of the k-th memory cell may have a negative channel voltage.

A channel voltage difference may occur between a lower channel and an upper channel with the k-th memory cell interposed therebetween. Due to the channel voltage difference, hot carrier injection (HCI) may occur in an adjacent memory cells MCk+1 and/or MCk−1. For this reason, threshold voltages of memory cells connected to adjacent word lines WLk+1 and/or WLk−1 may be distorted. For example, the threshold voltages of memory cells in the erased state E0 may rise to enter the programmed state.

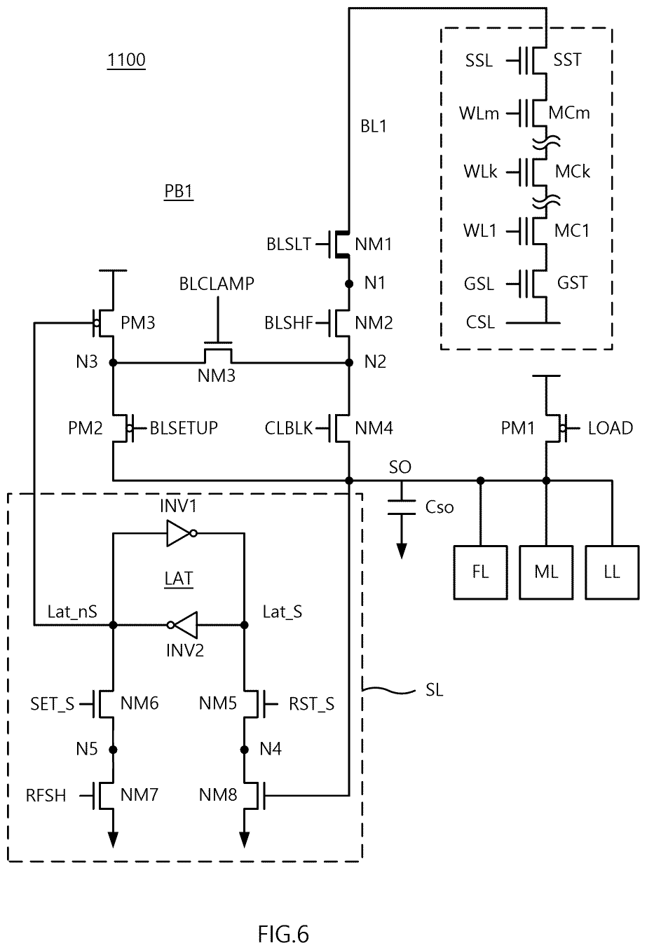

FIG. 6 is a circuit diagram illustrating the first page buffer PB1 shown in FIG. 5.

Referring to FIG. 6, the first page buffer PB1 may be connected to the first bit line BL1. A cell string may be connected to the first bit line BL1.

The cell string may include a string selection transistor SST, a plurality of memory cells MC1 to MCm, and a ground selection transistor GST. The cell string may be connected between the first bit line BL1 and the common source line CSL. The cell string may include a string selection transistor SST selected by a string selection line SSL, first to m-th memory cells MC1 to MCm connected to the first to m-th word lines WL1 to WLm, and a ground selection transistor GST selected by the ground selection line GSL. The k-th memory cell MCK may be a selected memory cell, and the k-th word line WLk may be a selected word line.

The first page buffer (PB1) may be connected to the cell string through the first bit line BL1. A first NMOS transistor NM1 may be included between the first bit line BL1 and the first node N1. The first NMOS transistor NM1 may be a bit line selection transistor driven by the bit line select signal BLSLT. The bit line selection transistor may be implemented as a high voltage transistor. The bit line selection transistor may be disposed in the high voltage region.

A second NMOS transistor NM2 may be included between the first node N1 and the second node N2. The second NMOS transistor NM2 may be a bit line shut-off transistor driven by the bit line shut-off signal BLSHF. A third NMOS transistor NM3 may be included between the second node N2 and the third node N3. The third NMOS transistor NM3 may be a bit line clamping transistor driven by the bit line clamping control signal BLCLAMP. A fourth NMOS transistor NM4 may be included between the second node N2 and the sensing node SO. The fourth NMOS transistor NM4 may be a bit line connection transistor driven by the bit line connection control signal CLBLK.

A first PMOS transistor PM1 may be included between the sensing node SO and the power terminal. The first PMOS transistor PM1 may be a precharge load transistor driven by the load signal LOAD. A second PMOS transistor PM2 may be included between the sensing node SO and the third node NM3. The second PMOS transistor PM2 may be a bit line setup transistor driven by the bit line setup signal BLSETUP. A third PMOS transistor PM3 may be included between the third node NM3 and the power terminal. The third PMOS transistor PM3 may be a precharge transistor driven by the inverted latch node Lat_nS.

A sensing latch SL, a force latch FL, a most significant bit latch ML, and a least significant bit latch LL may be connected to the sensing node SO. The sensing latch SL may store data stored in the selected memory cell sMC or a sensing result of the threshold voltage of the selected memory cell sMC during a read or program verify operation. Also, the sensing latch SL may be used to apply a program bit line voltage or a program inhibit voltage to the first bit line BL1 during a program operation. The force latch FL may be used to improve threshold voltage distribution during a program operation. The most significant bit latch ML and the least significant bit latch LL may be utilized to store data inputted from the outside during a program operation.

The sensing latch SL may include a latch LAT connected between the latch node Lat_S and the inverted latch node Lat_nS. The latch LAT may include first and second inverters INV1 and INV2. An input terminal of the first inverter INV1 and an output terminal of the second inverter INV2 may be connected to the inverted latch node Lat_nS. An output terminal of the first inverter INV1 and an input terminal of the second inverter INV2 may be connected to the latch node Lat_S.

The inverted latch node Lat_nS may be connected to the gate terminal of the third PMOS transistor PM3. When the inverted latch node Lat_nS is at a low level, the third PMOS transistor PM3 may be turned on, and the third node N3 may become a power supply voltage level. When the inverted latch node Lat_nS is at a high level, the power terminal and the third node N3 may be cut off.

A fifth NMOS transistor NM5 may be included between the latch node Lat_S and the fourth node N4. The fifth NMOS transistor NM5 may be used to reset the latch node Lat_S in response to the latch reset signal RST_S. The latch reset signal RST_S may be provided from the control logic 1160. A sixth NMOS transistor NM6 may be included between the inverted latch node Lat_nS and the fifth node N5. The sixth NMOS transistor NM6 may be used to set the latch node Lat_S in response to the latch set signal SET_S. The latch set signal SET_S may be provided from the control logic 1160.

A seventh NMOS transistor NM7 may be included between the fifth node N5 and the ground terminal. The seventh NMOS transistor NM7 may adjust the voltage level of the fifth node N5 in response to the refresh signal RFSH. The refresh signal RFSH may be provided from the control logic 1160. An eighth NMOS transistor NM8 may be included between the fourth node N4 and the ground terminal. The eighth NMOS transistor NM8 may adjust the voltage level of the fourth node N4 in response to the voltage level of the sensing node SO.

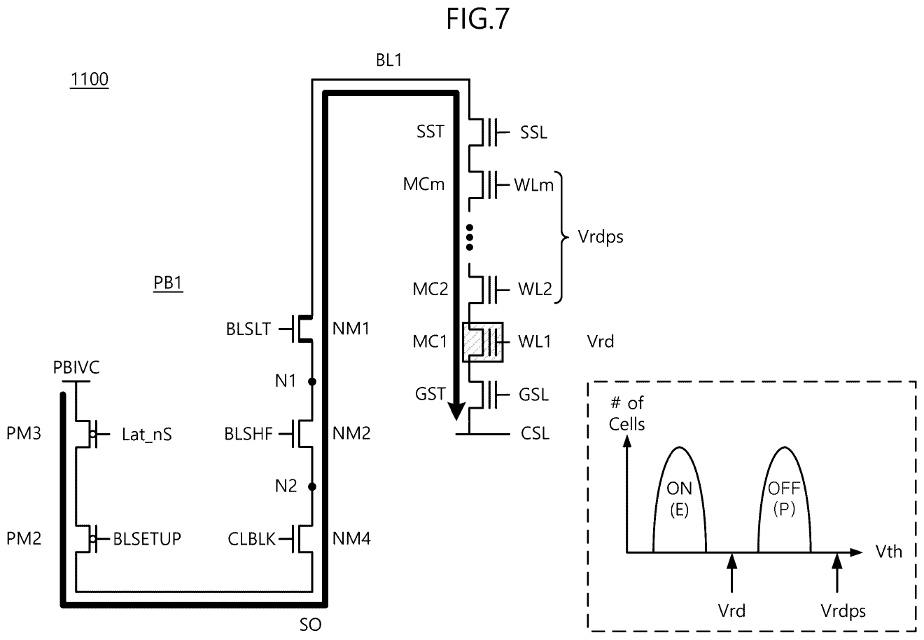

FIGS. 7 to 9 illustrate some implementations of an information data read operation of the first page buffer illustrated in FIG. 6. The memory device 1100 may read information data when powered up. The information data may be stored in memory cells (for example, MC1 to MCm) when the memory device 1100 is manufactured.

Referring to FIG. 7, the memory device 1100 may read information data stored in the first memory cell MC1 when powered up. The memory device 1100 may provide a selection read voltage Vrd to the first word line WL1 and a read pass voltage Vrdps to the second to m-th word lines (WL2 to WLm) to read the information data stored in the first memory cell MC1.

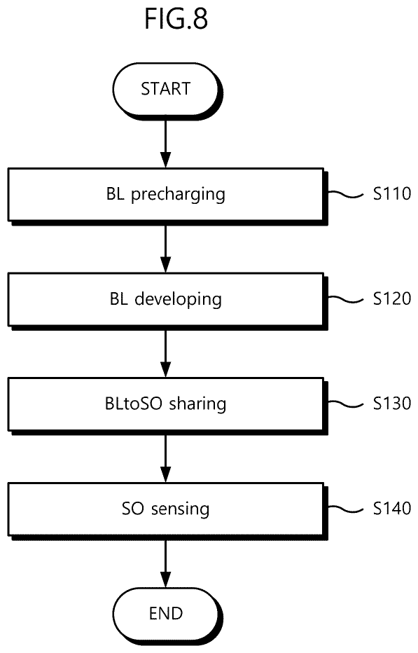

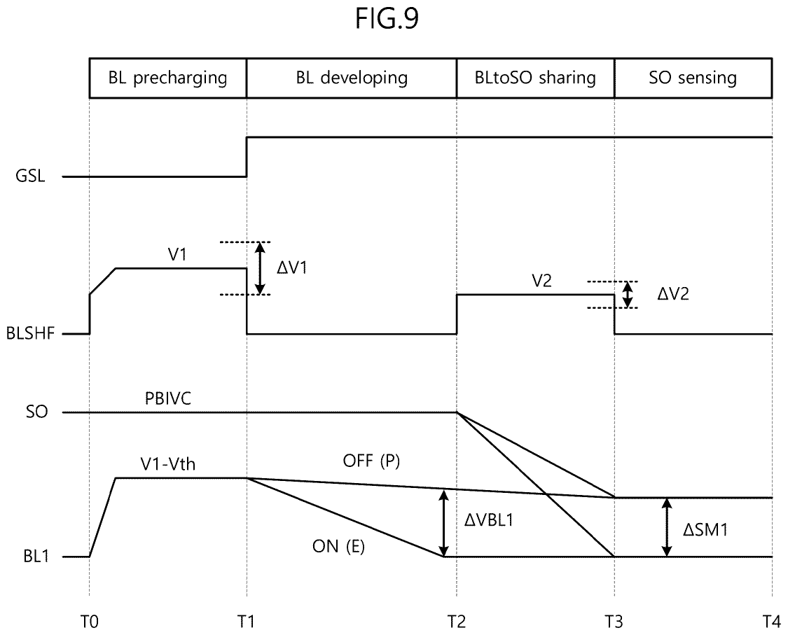

Referring to FIGS. 8 and 9, the information data read operation IDR may include a bit line precharge operation S110, a bit line develop operation S120, a BLtoSO sharing operation S130, and a SO sensing operation S140.

In operation S110, the first page buffer PB1 may perform a bit line precharge operation. During the bit line precharge time period (T0 to T1), the first NMOS transistor NM1, the second NMOS transistor NM2, the fourth NMOS transistor NM4, the second PMOS transistor PM2, and the third PMOS transistor PM3 may be turned on. In addition, a ground voltage may be provided to the ground selection line GSL, and the ground selection transistor GST may be turned off. During the bit line precharge operation, the page buffer internal voltage PBIVC may be provided to the third PMOS transistor PM3. The SO node may rise to the page buffer internal voltage PBIVC. A bit line shut-off signal BLSHF may be provided to the gate of the second NMOS transistor NM2. When the bit line shut-off signal BLSHF is at a V1 voltage level, the first bit line BL1 may be precharged to a V1-Vth voltage level. Here, Vth may be a threshold voltage of the second NMOS transistor NM2.

In operation S120, the first page buffer PB1 may perform a bit line develop operation. During the bit line develop time period (T1 to T2), a power voltage may be provided to the ground selection line GSL, and the ground selection transistor GST may be turned on. And the bit line shut-off signal BLSHF may be a ground level, and the second NMOS transistor NM2 may be turned off.

Depending on whether the first memory cell MC1 is an on cell or an off cell, the voltage level precharged to the first bit line BL1 may vary. If the first memory cell MC1 is an on cell or an erase state E, the precharged charge may be discharged through the common source line CSL. If the first memory cell MC1 is an off cell or a program state P, the precharged charge may be maintained. During the bit line develop operation, the difference in the bit line voltage level between the off cell and the on cell may be ΔVBL1.

In operation S130, the first page buffer PB1 may perform a BLtoSO sharing operation. During the BLtoSO sharing time period (T2 to T3), a charge sharing operation may be performed between the first bit line BL1 and the SO node. The bit line shut-off signal BLSHF having a V2 voltage level may be provided to the gate of the second NMOS transistor NM2. The V2 voltage level may be lower than the V1 voltage level. When the bit line shut-off signal BLSHF is at the V2 voltage level, charge sharing may occur between the first bit line BL1 and the SO node. At T3, the voltage level of the SO node may be equal to the voltage level of the first bit line BL1.

In operation S140, the first page buffer PB1 may perform a SO sensing operation. During the SO sensing time period (T3 to T4), the bit line shut-off signal BLSHF may be at a ground level, and the second NMOS transistor NM2 may be turned off. The sensing latch SL illustrated in FIG. 6 may perform an SO node sensing operation. If the first memory cell MC1 is an off cell, the SO node may maintain a precharge voltage level. If the first memory cell MC1 is an on cell, the SO node may be a ground level. During the SO sensing operation, the SO node sensing margin between the off cell and the on cell may be ΔSM1.

During the information data read operation, the voltage levels of signals applied to the first bit line BL1 are not constant and may have a certain degree of voltage skew or time skew. For example, as illustrated in FIG. 9, the bit line shut-off signal BLSHF may have a voltage skew of ΔV1 during the bit line precharge operation and a voltage skew of ΔV2 during the BLtoSO sensing operation. As the memory device 1100 develops toward low power consumption, the page buffer internal voltage PBIVC may also be lowered. Due to skew of signals applied to the first page buffer PB1 and a decrease in internal voltage, a sufficient sensing margin may not be secured and a sensing failure may occur.

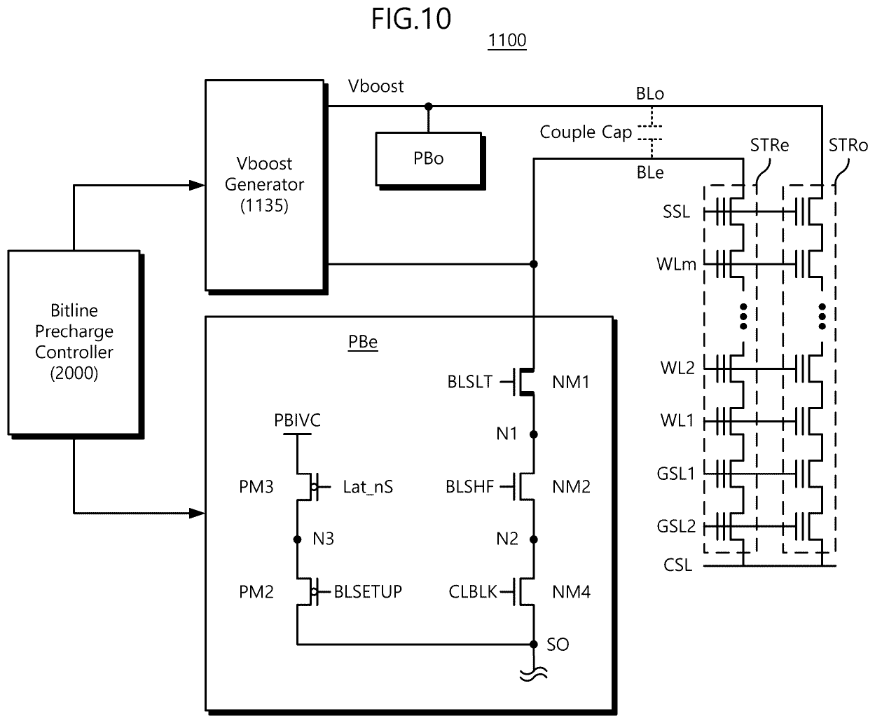

FIG. 10 is a circuit diagram illustrating some implementations of the memory device according to the present disclosure. The memory device 1100 may sufficiently secure a sensing margin during an information data read operation by using a couple cap between neighboring bit lines. Referring to FIG. 10, the neighboring bit lines may be an even bit line BLe and an odd bit line BLo.

The even page buffer PBe may be connected to the even bit line BLe. The odd page buffer PBo may be connected to the odd bit line BLo. For example, the second page buffer PB2 may be connected to the second bit line BL2, and the third page buffer PB3 may be connected to the third bit line BL3.

The even bit line BLe may be connected to an even cell string STRe, and the odd bit line BLo may be connected to an odd cell string STRo. Each cell string may be connected to a string selection transistor connected to a string selection line SSL, memory cells connected to a plurality of word lines (WL1, WL2, . . . , WLm), and ground selection transistors connected to first and second ground selection lines (GSL1, GSL2).

A first NMOS transistor NM1 may be included between the even bit line BLe and the first node N1. The first NMOS transistor NM1 may be a bit line selection transistor driven by a bit line select signal BLSLT. The bit line selection transistor may be implemented as a high voltage transistor. The bit line selection transistor may be placed in a high voltage region.

A second NMOS transistor NM2 may be included between the first node N1 and the second node N2. The second NMOS transistor NM2 may be a bit line shut-off transistor driven by a bit line shut-off signal BLSHF. A fourth NMOS transistor NM4 may be included between the second node N2 and the sensing node SO. The fourth NMOS transistor NM4 may be a bit line connection transistor driven by a bit line connection control signal CLBLK.

A second PMOS transistor PM2 may be included between the sensing node SO and the third node N3. The second PMOS transistor PM2 may be a bit line setup transistor driven by a bit line setup signal BLSETUP. A third PMOS transistor PM3 may be included between the third node N3 and the power terminal. The third PMOS transistor PM3 may be a precharge transistor driven by an inverted latch node Lat_nS. During an information data read operation, a page buffer internal voltage PBIVC may be provided to the power terminal of the third PMOS transistor PM3.

The memory device 1100 may include a boost voltage generator 1135. The boost voltage generator 1135 may provide a boost voltage Vboost to an even bit line BLe or an odd bit line BLo during an information data read operation. When an information data read operation is performed for an even bit line BLe, the boost voltage generator 1135 may provide a boost voltage Vboost to an odd bit line BLo. When an information data read operation is performed for an odd bit line BLo, the boost voltage generator 1135 may provide a boost voltage Vboost to an even bit line BLe.

The bit line precharge controller 2000 may provide control signals to the boost voltage generator 1135 and the page buffers (PBe or PBo) during an information data read operation. The bit line precharge controller 2000 may control to provide a boost voltage Vboost to an odd bit line BLo when an information data read operation is performed for an even bit line BLe. When a boost voltage Vboost is provided to an odd bit line BLo, the voltage level of an even bit line BLe may be increased by a couple cap. Here, the couple cap may be a parasitic capacitance existing between neighboring bit lines. When the voltage level of the even bit line BLe is increased by the couple cap, the sensing margin may be increased during an information data read operation.

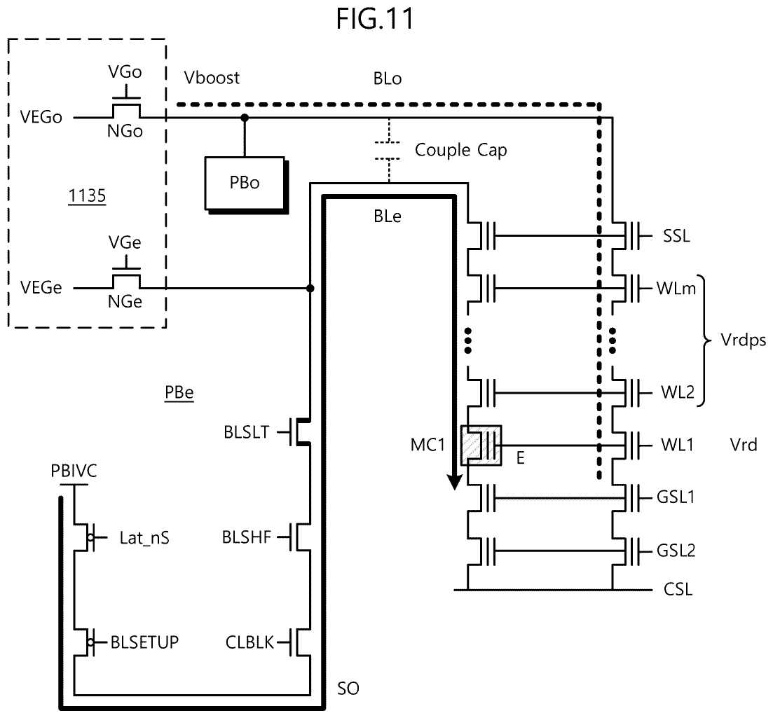

FIGS. 11 to 13 illustrate some implementations of an information data read operation of a memory device according to the present disclosure. The memory device 1100 may read information data stored in the first memory cell MC1 when powered up. The memory device 1100 may provide a selection read voltage Vrd to the first word line WL1 and a read pass voltage Vrdps to the second to m-th word lines (WL2 to WLm) to read information data stored in the first memory cell MC1.

Referring to FIG. 11, the boost voltage generator 1135 may include NMOS transistors. Each NMOS transistor may be a gidl transistor. An even NMOS gidl transistor NGe may be connected to an even bit line BLe. An odd NMOS gidl transistor NGo may be connected to an odd bit line BLo. An even erase gidl voltage VEGe may be provided to a drain of the even NMOS transistor NGe, and an even gidl gate voltage VGe may be provided to a gate of the even NMOS transistor NGe. An odd erase gidl voltage VEGo may be provided to a drain of the odd NMOS transistor NGo, and an odd gidl gate voltage VGo may be provided to a gate the odd NMOS transistor NGo.

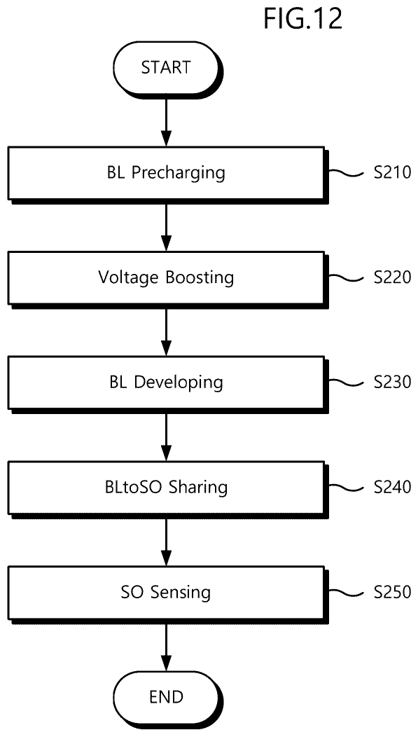

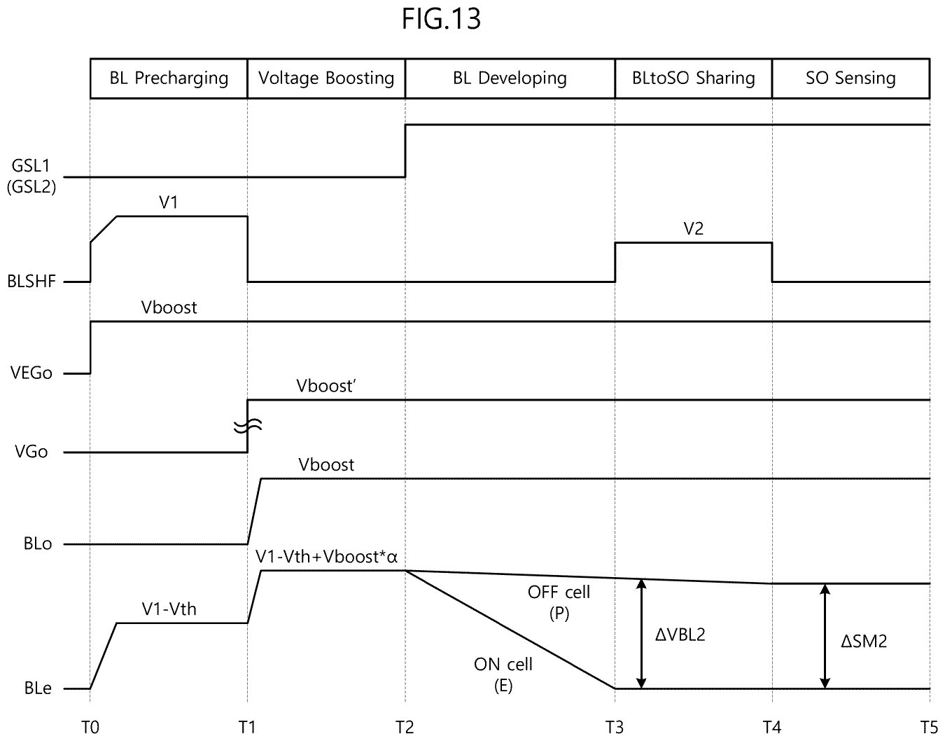

Referring to FIGS. 12 and 13, an information data read operation IDR may include a bit line precharge operation S210, a voltage boosting operation S220, a bit line develop operation S230, a BLtoSO sharing operation S240, and a SO sensing operation S250.

In operation S210, the even page buffer PBe may perform a bit line precharge operation. During the bit line precharge time period (T0˜T1), the page buffer internal voltage PBIVC may be provided. The SO node may be increased to the page buffer internal voltage PBIVC. If the bit line shut-off signal BLSHF is at a V1 voltage level, the even bit line BLe may be precharged to a V1-Vth voltage level. Here, Vth may be a threshold voltage of the shut-off NMOS transistor.

In operation S220, a voltage boosting operation for the odd bit line BLo may be performed. During or before the voltage boosting time period T1˜T2, an odd erase voltage VEGo may be provided to the drain of the odd NMOS transistor NGo. The odd erase voltage VEGo may be a boost voltage Vboost. A boost high voltage Vboost′ sufficiently higher than the boost voltage Vboost may be provided to the gate of the odd NMOS gate transistor NGo. The boost high voltage Vboost′ may be a gate voltage for transferring the boost voltage Vboost to the odd bit line BLo.

The bit line shut-off signal BLSHF may have a ground level, and the bit line shut-off transistor may be turned off. When the boost high voltage Vboost′ is provided, the odd bit line BLo may be increased to the boost voltage Vboost. When the odd bit line BLo is increased to the boost voltage Vboost, the even bit line BLe may be increased by the boost voltage*a by the couple cap. Here, α may be a coupling ratio. The voltage level of the even bit line BLe may be V1-Vth+Vboost*α.

In operation S230, the even page buffer PBe may perform a bit line develop operation. During the bit line develop time period (T2 to T3), a power voltage is supplied to the ground selection lines (GSL1, GSL2), and the ground selection transistors may be turned on. The bit line shut-off signal BLSHF may maintain a ground level.

Depending on whether the first memory cell MC1 is an on cell or an off cell, the voltage level precharged to the even bit line BLe may vary. If the first memory cell MC1 is an on cell or an erase state E, the precharged charge may be discharged through the common source line CSL. If the first memory cell MC1 is an off cell or a program state P, the precharged charge may be maintained. During the bit line develop operation, the difference in the bit line voltage level between the off cell and the on cell may be ΔVBL2.

In operation S240, the even page buffer PBe may perform a BLtoSO sharing operation. During the BLtoSO sharing time period (T3 to T4), a charge sharing operation may be performed between the even bit line BLe and the SO node. When the bit line shut-off signal BLSHF is at the V2 voltage level, charge sharing may occur between the even bit line BLe and the SO node. At T4, the voltage level of the SO node may be equal to the voltage level of the even bit line BLe.

In operation S250, the even page buffer PBe may perform a SO sensing operation. During the SO sensing time period (T4 to T5), the bit line shut-off signal BLSHF may be at the ground level. The sensing latch SL illustrated in FIG. 6 may perform the SO node sensing operation. If the first memory cell MC1 is an off cell, the SO node may maintain the precharge voltage level. If the first memory cell MC1 is an on cell, the SO node may be at the ground level. During the SO sensing operation, the SO node sensing margin between the off cell and the on cell may be ΔSM2.

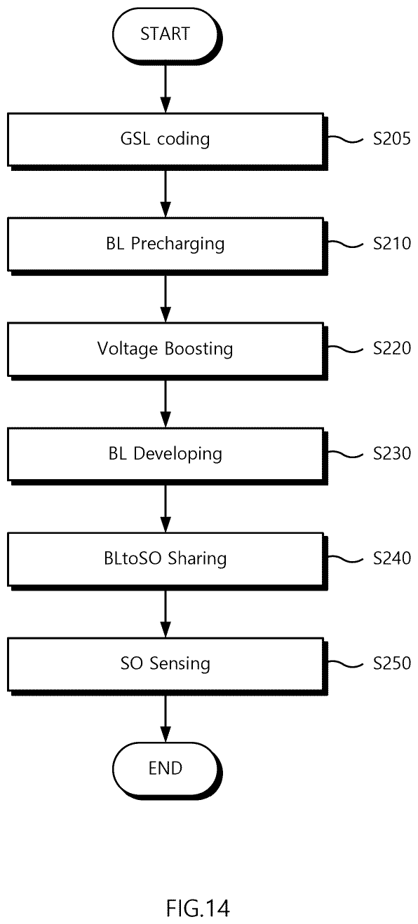

FIGS. 14 to 17 illustrate some implementations of a method for performing an information data read operation using a GSL coding method. The memory device 1100 may increase the sensing margin of the selected bit lines by applying a boosting voltage Vboost through the unselected bit lines during the information data read operation. The memory device 1100 may block the current path of the unselected bit lines during the voltage boosting operation using the GSL coding method.

Referring to FIG. 14, in operation S205, the memory device 1100 may perform the GSL coding operation before the bit line precharge operation. The GSL coding operation may be performed by programming the ground selection transistors connected to the unselected bit lines to an off-cell state. The memory device 1100 may prevent cell current from flowing to the unselected bit lines during the voltage boosting operation through the GSL coding operation.

The bit line precharge operation S210, the voltage boosting operation S220, the bit line develop operation S230, the BLtoSO sharing operation S240, and the SO sensing operation S250 are as described in FIG. 12.

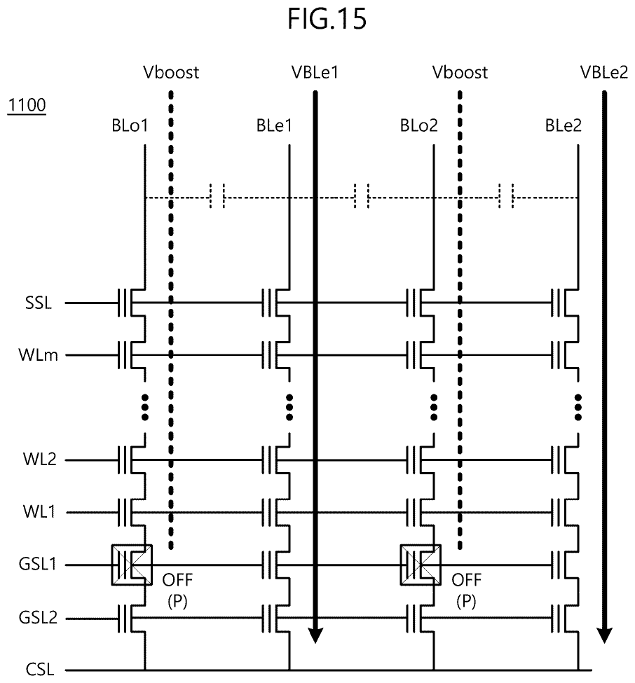

Referring to FIG. 15, the unselected bit lines may be odd bit lines (BLo1, BLo2) and the selected bit lines may be even bit lines (BLe1, BLe2). The even bit lines (BLe1, BLe2) may increase the bit line voltage level by using the boosting voltage Vboost of the odd bit lines (BLo1, BLo2) during the information data read operation. The memory device 1100 may code the first ground selection line GSL1 so that the cell current does not flow to the odd bit lines (BLo1, BLo2) during the voltage boosting operation.

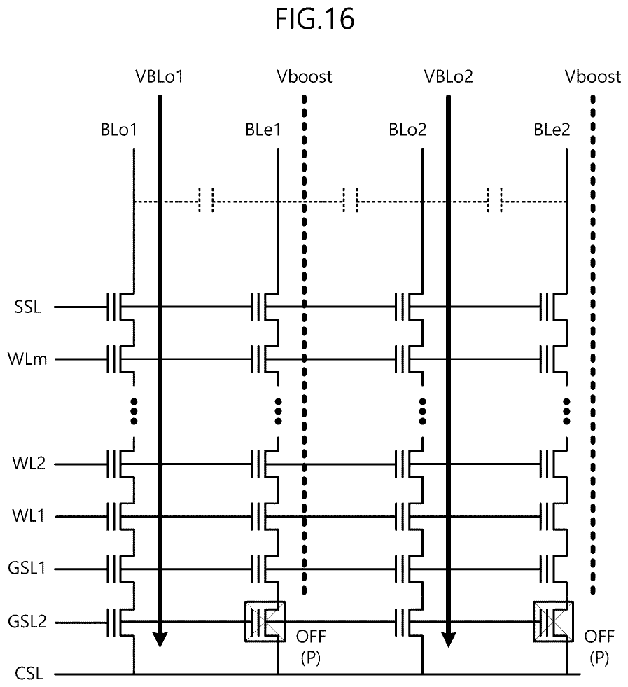

Referring to FIG. 16, the unselected bit lines may be even bit lines (BLe1, BLe2) and the selected bit lines may be odd bit lines (BLo1, BLo2). The odd bit lines (BLo1, BLo2) may increase the bit line voltage level by using the boosting voltage Vboost of the even bit lines (BLe1, BLe2) during the information data read operation. The memory device 1100 may code the second ground selection line GSL2 so that the cell current does not flow to the even bit lines (BLe1, BLe2) during the voltage boosting operation.

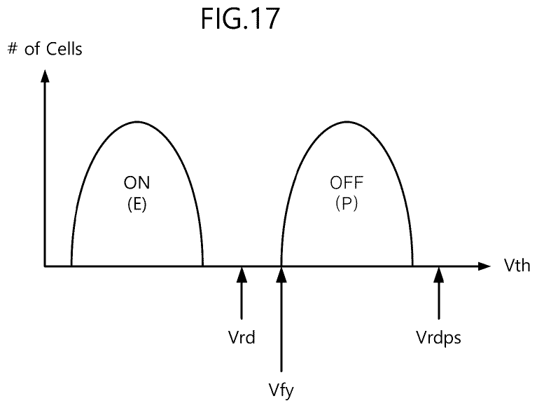

The memory device 1100 may perform a GSL coding operation by programming ground selection transistors connected to ground selection lines (GSL1 or GSL2) to an off-cell state. For example, odd ground selection transistors connected to the first ground selection line GSL1 may be programmed to an off-cell state. Alternatively, even ground selection transistors connected to the second ground selection line GSL2 may be programmed to an off-cell state. Referring to FIG. 17, the memory device 1100 may program the ground selection transistors to an off-cell state using a program verify voltage Vfy.

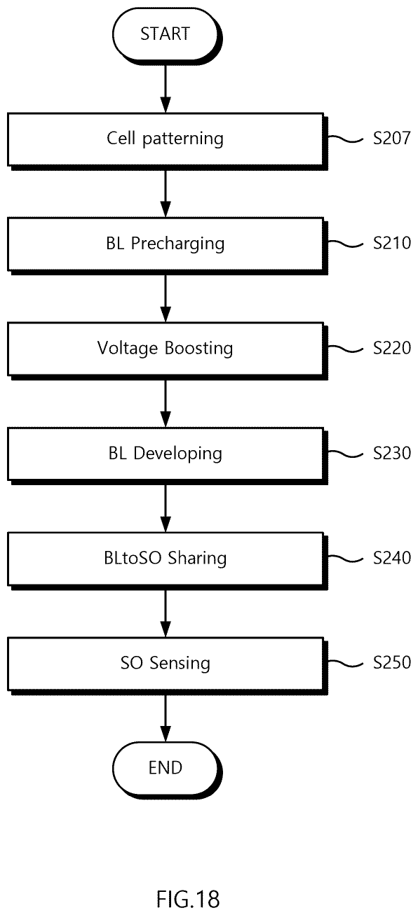

FIGS. 18 to 20 illustrate some implementations of a method for performing an information data read operation using a cell patterning method. The memory device 1100 may block the current path of unselected bit lines during a voltage boosting operation using the cell patterning method.

Referring to FIG. 18, in operation S207, the memory device 1100 may perform a cell patterning operation before the bit line precharge operation. The cell patterning operation may be performed by programming memory cells connected to the unselected bit lines to an off-cell state. The memory device 1100 may prevent cell current from flowing to the unselected bit lines during the voltage boosting operation through the cell patterning operation. The bit line precharge operation S210, the voltage boosting operation S220, the bit line develop operation S230, the BLtoSO sharing operation S240, and the SO sensing operation S250 are as described in FIG. 12.

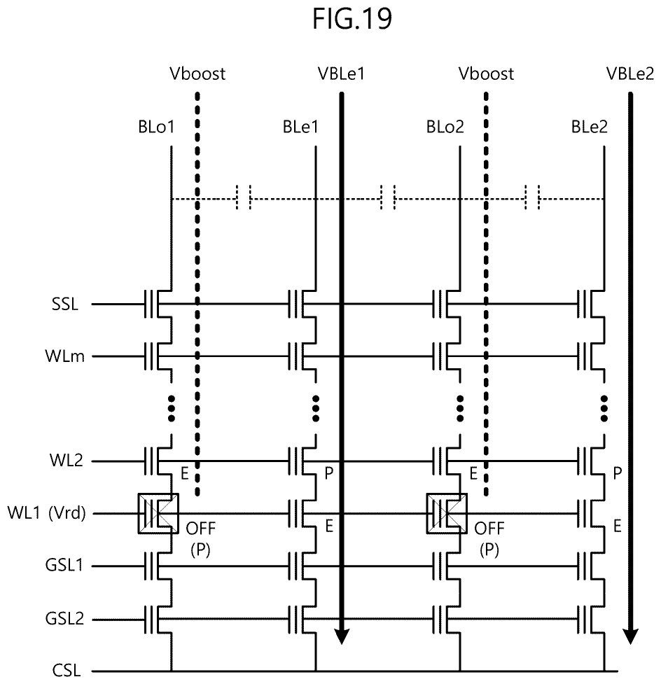

Referring to FIG. 19, the unselected bit lines may be odd bit lines (BLo1, BLo2) and the selected bit lines may be even bit lines (BLe1, BLe2). The even bit lines (BLe1, BLe2) may increase the bit line voltage level by the boosting voltage Vboost of odd bit lines (BLo1, BLo2) during the information data read operation.

The memory device 1100 may cell pattern the first word lines WL1 so that the cell current does not flow to the odd bit lines (BLo1, BLo2) during the voltage boosting operation. The memory device 1100 may perform a cell patterning operation by programming memory cells connected to the odd bit lines (BLo1, BLo2) among the memory cells connected to the first word line WL1 to an off-cell state.

The memory device 1100 may program the memory cells connected to the odd bit lines (BLo1, BLo2) to an off-cell state using a program verify voltage Vfy. When the selection read voltage Vrd is provided to the first word line WL1 during an information data read operation, the current path of the odd bit lines (BLo1, BLo2) may be blocked so that cell current may not flow.

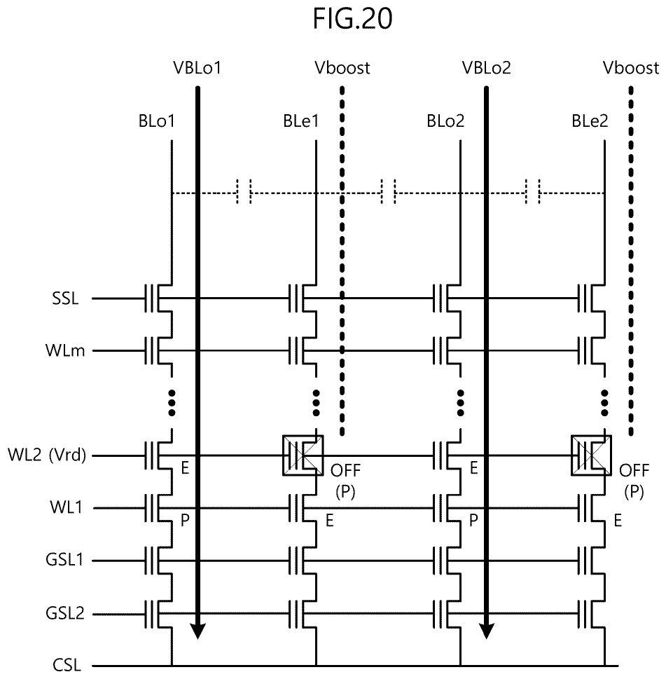

Referring to FIG. 20, the unselected bit lines may be even bit lines (BLe1, BLe2) and the selected bit lines may be odd bit lines (BLo1, BLo2). The odd bit lines (BLo1, BLo2) may increase the bit line voltage level by the boosting voltage Vboost of the even bit lines (BLe1, BLe2) during the information data read operation.

The memory device 1100 may cell pattern the second word lines WL2 so that the cell current does not flow to the even bit lines (BLe1, BLe2) during the voltage boosting operation.

The memory device 1100 may perform the cell patterning operation by programming the memory cells connected to the even bit lines (BLe1, BLe2) among the memory cells connected to the second word line WL2 to an off-cell state. When the selection read voltage Vrd is provided to the second word line WL2 during the information data read operation, current paths of the even bit lines (BLe1, BLe2) are blocked, and cell current may not flow.

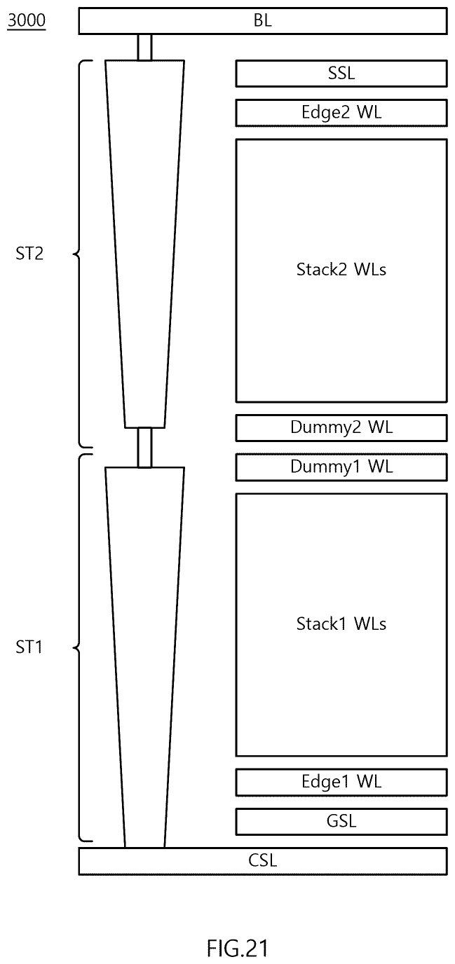

FIG. 21 is a diagram illustrating some implementations of a memory device having a multi-stack structure. Referring to FIG. 21, the memory device 3000 may have a first stack ST1 and a second stack ST2. The first stack ST1 may be located at the bottom, and the second stack ST2 may be located at the top.

A pillar of the memory device 3000 may be formed by bonding the first and second stacks ST1 and ST2. A plurality of dummy word lines (e.g., Dummy1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TLC or QLC.

When powering up, the memory device 3000 may perform an information data read operation using a couple cap that parasitically exists between neighboring bit lines. The memory device 3000 may code the ground selection line GSL in the first stack ST1. Alternatively, the memory device 3000 may perform cell patterning on the first edge word line Edge1 WL or the first stack word lines Stack1 WLs in the first stack ST1. During an information data read operation, the memory device 3000 may increase the information data sensing margin of the selected bit line by using a couple cap between the selected bit line and the unselected bit line.

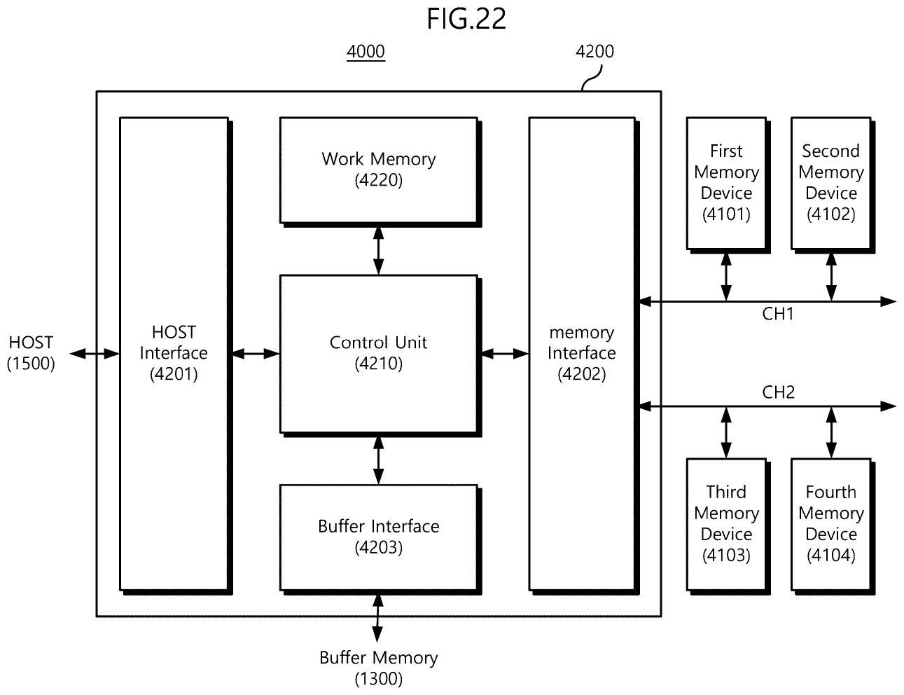

FIG. 22 is a block diagram illustrating an example in which a storage device according to some implementations of the present disclosure is implemented with a solid state drive (SSD).

FIG. 22 is a block diagram illustrating an example in which a storage device according to some implementations of the present disclosure is implemented with a solid state drive (SSD). Referring to FIG. 22, an SSD 4000 may include a plurality of memory devices 4101 to 4104 and an SSD controller 4200.

The first and second memory devices 4101 and 4102 may be connected with the SSD controller 4200 through a first channel CH1. The third and fourth memory devices 4103 and 4104 may be connected with the SSD controller 4200 through a second channel CH2. The number of channels connected with the SSD controller 4200 may be 2 or more. The number of memory devices connected with one channel may be 2 or more.

The SSD controller 4200 may include a host interface 4201, a memory interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding memory device or may read data from the corresponding memory device.

The SSD controller 4200 may be connected with the plurality of memory devices 4101 to 4104 through the memory interface 4202 and may be connected with a buffer memory 1300 through the buffer interface 4203. The memory interface 4202 may provide data, which are temporarily stored in the buffer memory 1300, to the plurality of memory devices through the channels CH1 and CH2. The memory interface 4202 may transfer the data read from the plurality memory devices 4101 to 4104 to the buffer memory 1300.

The control unit 4210 may analyze and process the signal received from the host 1500. The control unit 4210 may control the host 1500 or the plurality memory devices 4101 to 4104 through the host interface 4201 or the memory interface 4202. The control unit 4210 may control operations of the plurality memory devices 4101 to 4104 by using firmware for driving the SSD 4000.

The SSD controller 4200 may manage data to be stored in the plurality of memory devices 4101 to 4104. In the sudden power-off event, the SSD controller 4200 may back the data stored in the work memory 4220 or the buffer memory 1300 up to the plurality of memory devices 4101 to 4104.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory device, comprising:
a first bit line connected to a first cell string;
a second bit line connected to a second cell string and adjacent to the first bit line; and
a boost voltage generator,
wherein the boost voltage generator is configured to precharge the first bit line, apply a boost voltage to the second bit line, and sense data stored in the first cell string, wherein a precharge voltage level of the first bit line is increased due to a coupled capacitance between the first bit line and the second bit line.

2. The memory device of claim 1,
wherein the boost voltage generator includes an NMOS transistor, and
wherein an output of the boost voltage generator is coupled to a drain of the NMOS transistor, and a voltage higher than a sum of the boost voltage and a threshold voltage of the NMOS transistor is provided to a gate of the NMOS transistor.

3. The memory device of claim 1,
wherein the second cell string includes:
a string selection transistor arranged to be controlled by a string selection line;
a plurality of memory cells connected to the string selection transistor and arranged to be controlled by a plurality of word lines; and
a ground selection transistor connected to the plurality of memory cells and arranged to be controlled by a ground selection line.

4. The memory device of claim 3,
wherein a bit line precharge controller is configured to program the ground selection transistor to an off-cell state before applying the boost voltage to the second bit line.

5. The memory device of claim 3,
wherein a bit line precharge controller is configured to program at least one of the plurality of memory cells of the second cell string to an off-cell state before applying the boost voltage to the second bit line.

6. A memory device, comprising:
a first bit line connected to a first cell string;
a second bit line connected to a second cell string and adjacent to the first bit line; and
a bit line precharge controller configured to control voltage levels of the first bit line and the second bit line during an information data read operation to read data stored in the first cell string,
wherein the bit line precharge controller is configured to precharge the first bit line, provide a boost voltage to the second bit line such that a precharge voltage level of the first bit line is increased, and sense the data stored in the first cell string.

7. The memory device of claim 6,
wherein the first bit line and the second bit line are arranged such that, during operation of the memory device, a coupling capacitance between the first bit line and the second bit line increases the precharge voltage level of the first bit line.

8. The memory device of claim 6, further comprising:
a boost voltage generator configured to provide the boost voltage to the second bit line,
wherein the bit line precharge controller is configured to control the boost voltage generator.

9. The memory device of claim 8,
wherein the boost voltage generator includes an NMOS transistor.

10. The memory device of claim 9,
wherein an output of the boost voltage generator is coupled to a drain of the NMOS transistor, and
wherein the bitline precharge controller is configured to provide a voltage higher than a sum of the boost voltage and a threshold voltage of the NMOS transistor to a gate of the NMOS transistor.

11. The memory device of claim 10,
wherein the boost voltage generator is configured to provide the boost voltage during an erase operation of the memory device.

12. The memory device of claim 6, wherein the second cell string includes:
a string selection transistor configured to be controlled by a string selection line;
a plurality of memory cells connected to the string selection transistor and configured to be controlled by a plurality of word lines;
a first ground selection transistor connected to the plurality of memory cells and configured to be controlled by a first ground selection line; and
a second ground selection transistor connected to the first ground selection transistor and configured to be controlled by a second ground selection line.

13. The memory device of claim 12,
wherein the bit line precharge controller is configured to program the first or second ground selection transistor to an off-cell state before providing the boost voltage to the second bit line.

14. The memory device of claim 12,
wherein the bit line precharge controller is configured to program at least one of the plurality of memory cells of the second cell string to an off-cell state before providing the boost voltage to the second bit line.

15. The memory device of claim 6,
wherein the first and second cell strings are stacked in a direction perpendicular to a substrate.

16. A method for reading information data of a memory device, wherein the memory device includes a first bit line connected to a first cell string, and a second bit line connected to a second cell string and adjacent to the first bit line, wherein the method comprises:
during an information data read operation, precharging the first bit line;
applying a boost voltage to the second bit line;
waiting for the first bit line to develop;
performing a charge sharing operation between the first bit line and a sensing node; and
sensing data stored in the first cell string,
wherein a precharge voltage level of the first bit line is increased due to a parasitic coupling capacitance that exists between the first bit line and the second bit line when the boost voltage is applied to the second bit line.

17. The method of claim 16,
wherein, before applying the boost voltage to the second bit line, a ground selection transistor of the second cell string is programmed to an off-cell state.

18. The method of claim 16,
wherein, before applying the boost voltage to the second bit line, at least one of a plurality of memory cells of the second cell string is programmed to an off-cell state.

19. The method of claim 16,
wherein the memory device comprises:
a third bit line connected to a third cell string and adjacent to the second bit line; and
a fourth bit line connected to a fourth cell string and adjacent to the third bit line,
wherein, during the information data read operation, the first and third bit lines are precharged, a boost voltage is applied to the second and fourth bit lines, the precharge voltage level of the first and third bit lines is increased due to a parasitic coupling capacitance existing between the first to fourth bit lines, and then data stored in the first and third cell strings are sensed.

20. The method of claim 19,
wherein, before applying the boost voltage to the second and fourth bit lines, ground selection transistors of the second and fourth cell strings are programmed to an off-cell state.
